(19) United States
(12) Patent Application Publication
(10) Pub. No.: US 2019/0035946 A1
(43) Pub. Date: Jan. 31, 2019

(54) SOLAR CELL WAFER

(71) Applicant: Sino-American Silicon Products Inc., Hsinchu (TW)

(72) Inventors: Cheng-Jui Yang, Hsinchu (TW); Jian-Jia Huang, Hsinchu (TW); Ming-Kung Hsiao, Hsinchu (TW); Cheng-Wei Gu, Hsinchu (TW); Bo-Kai Wang, Hsinchu (TW); Wen-Huai Yu, Hsinchu (TW); I-Ching Li, Hsinchu (TW); Sung-Lin Hsu, Hsinchu (TW); Wen-Ching Hsu, Hsinchu (TW)

(73) Assignee: Sino-American Silicon Products Inc., Hsinchu (TW)

(21) Appl. No.: 15/964,082

(22) Filed: Apr. 27, 2018

(30) Foreign Application Priority Data
Jul. 27, 2017 (TW) 106125267

(51) Int. Cl. H01L 31/028; H01L 31/04

(52) U.S. Cl. CPC H01L 31/0284; H01L 31/04

(57) ABSTRACT

A solar cell wafer is provided. It is a silicon wafer, and a surface of the silicon wafer has a plurality of pores, wherein based on a total amount of 100% of the plurality of pores, 60% or more of the pores has a circularity greater than 0.5. Therefore, the reflectance of the solar cell wafer can be efficiently reduced.

### CROSS-REFERENCE TO RELATED APPLICATION

This application claims the priority benefit of Taiwan application serial no. 106125267, filed on Jul. 27, 2017. The entirety of the above-mentioned patent application is hereby incorporated by reference herein and made a part of this specification.

### BACKGROUND OF THE INVENTION

### Field of the Invention

The invention relates to a wafer structure, and more particularly, to a solar cell wafer having a specific surface structure.

### Description of Related Art

The silicon wafer is currently one of the main materials of the substrate applied in various techniques, such as the solar cell silicon wafer.

The silicon wafer is generally formed by cutting via a diamond wire (DW), but a surface cut by the DW is too bright, such that the reflectance thereof is too high in comparison to the traditional slurry wire (SW) cutting. In other words, incident light is readily reflected by the surface, such that the photoelectric conversion efficiency of the solar cell is worsened.

### SUMMARY OF THE INVENTION

The invention relates to a solar cell wafer that can effectively reduce surface reflectance to increase the photoelectric conversion efficiency of a solar cell.

The solar cell wafer of the invention is a silicon wafer. A surface of the silicon wafer has a plurality of pores, wherein based on a total amount of 100% of the pores, 60% or more of the pores has a circularity greater than 0.5.

In an embodiment of the invention, based on a total amount of 100% of the pores, 40% or more of the pores has a circularity greater than 0.6.

In an embodiment of the invention, based on a total amount of 100% of the pores, 20% or more of the pores has a circularity greater than 0.7.

In an embodiment of the invention, based on a total amount of 100% of the pores, 70% or more of the pores has a diameter of pore less than 2.0 μm.

In an embodiment of the invention, based on a total amount of 100% of the pores, 50% or more of the pores has a diameter of pore less than 1.5 vim.

In an embodiment of the invention, based on a total amount of 100% of the pores, 25% or more of the pores has a diameter of pore less than 1.0 μm.

In an embodiment of the invention, based on a total amount of 100% of the pores, 90% or more of the pores has an aspect ratio less than 2.5.

In an embodiment of the invention, based on a total amount of 100% of the pores, 80% or more of the pores has an aspect ratio less than 2.0.

In an embodiment of the invention, based on a total amount of 100% of the pores, 60% or more of the pores has an aspect ratio less than 1.5.

In an embodiment of the invention, the pore density of the pores is between 6.5×10⁶ ea/cm² and 6.5×10⁷ ea/cm².

In an embodiment of the invention, the morphology of the pores is obtained via the analysis of the ImageJ software, and the operating setting of the ImageJ software is as follows: an original image is obtained by fixing an SEM magnification at 3000×, wherein a size of the original image opened by the ImageJ is 1280×960 pxl; the image size is reduced from 1280×960 pxl to 1280×850 pxl; the original grayscale distribution of the original image is analyzed, and the original grayscale distribution is adjusted to a distribution of 0 to 255, wherein the new grayscale=(original grayscale-Min)×[255/(Max-Min)], Max refers to a maximum value of the original grayscale, and Min refers to a minimum value of the original grayscale; the image grayscale threshold is set and selected pore locations are defined, and the grayscale threshold=0 to 50; the black and white boundaries are adjusted via a preset function to remove the black spots; and incomplete pores at the image edge are removed and the lower limit of pore size is defined, wherein the lower limit is 0.1 μm².

In an embodiment of the invention, the ratio of depth to diameter of the pore is between 0.1 and 1.5.

In an embodiment of the invention, the surface of the silicon wafer is a light-receiving surface.

In an embodiment of the invention, the reflectance of the surface of the silicon wafer is 25% or less.

Based on the above, in the invention, via the silicon wafer surface having a specific morphology, the reflectance thereof can be effectively reduced, such that the photoelectric conversion efficiency of the solar cell is increased. Moreover, in the invention, an image analysis software (ImageJ software) with specific operating settings is also used, and therefore the specific morphology of the silicon wafer surface can be obtained via accurate analysis.

In order to make the aforementioned features and advantages of the disclosure more comprehensible, embodiments accompanied with figures are described in detail below.

### BRIEF DESCRIPTION OF THE DRAWINGS

The accompanying drawings are included to provide a further understanding of the invention, and they are incorporated in and constitute a part of this specification. The drawings illustrate embodiments of the invention and, together with the description, serve to explain the principles of the invention.

FIG. 1A is a top view of a solar cell wafer according to an embodiment of the invention.

FIG. 1B is a cross section of the solar cell wafer of FIG. 1A.

FIG. 2A to FIG. 2F are operation schematics of the ImageJ software for obtaining pore morphology in the invention.

FIG. 3 is the image of comparative example 1 obtained by the ImageJ software.

FIG. 4 is an image of experimental example 1 obtained by the ImageJ software.

FIG. 5 is an image of experimental example 2 obtained by the ImageJ software.

FIG. 6 is bar chart of pore morphology of comparative example 1.

FIG. 7 is bar chart of pore morphology of experimental example 1.

FIG. 8 is bar chart of pore morphology of experimental example 2.

FIG. 9 is an SEM image of the cross section of the solar cell wafer of comparative example 1.

FIG. 10 is an SEM image of the cross section of the solar cell wafer of experimental example 1.

FIG. 11 is an SEM image of the cross section of the solar cell wafer of experimental example 2.

FIG. 12 is a comparison diagram of reflectance and efficiency of experimental examples 1 to 2 and comparative examples 1 to 2.

FIG. 13 is a curve diagram of reflectance of experimental examples 1 to 2 and comparative examples 1 to 2.

### DESCRIPTION OF THE EMBODIMENTS

Exemplary embodiments of the invention are comprehensively described hereinafter with reference to figures, but the invention can be implemented in many different forms and should not be construed as limited to the embodiments of the present specification. In the figures, for clarity, the size and thickness of each region, part, and layer may not be shown according to scale.

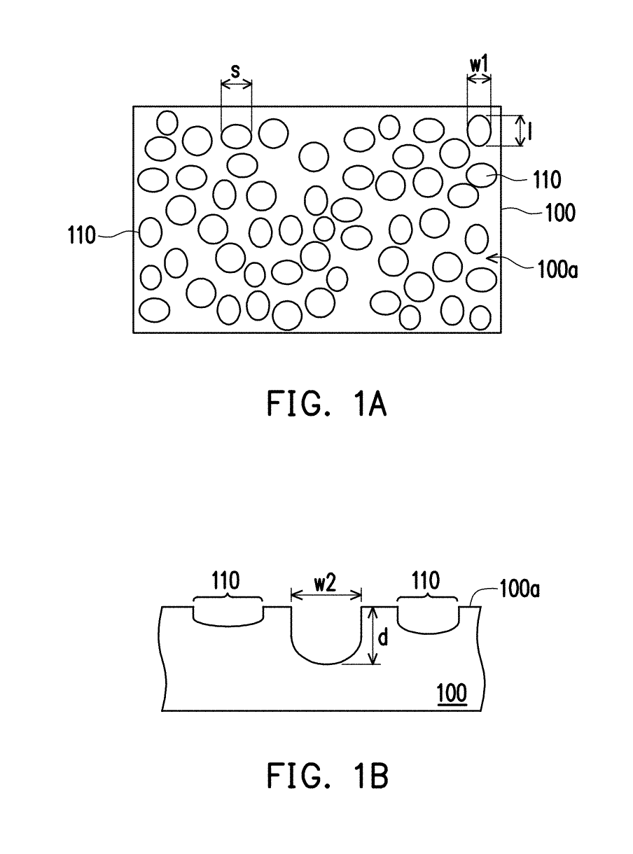

FIG. 1A is a top view of a solar cell wafer according to an embodiment of the invention. FIG. 1B is a cross section of the solar cell wafer of FIG. 1A.

Referring to FIG. 1A and FIG. 1B, a solar cell wafer of the present embodiment is a silicon wafer 100. A surface 100a of the silicon wafer 100 has a plurality of pores 110, wherein the surface 100a can be a light-receiving surface. Based on a total amount of 100% of the pores 110,60% or more of the pores has a circularity greater than 0.5. Therefore, the reflectance of the surface 100a of the silicon wafer 100 is 25% or less. In another embodiment, based on a total amount of 100% of the pores 110, 40% or more of the pores has a circularity greater than 0.6. In yet another embodiment, based on a total amount of 100% of the pores 110, 20% or more of the pores has a circularity greater than 0.7. The so-called “circularity” is obtained by calculating with the formula [4π(area)±(circumference)²], wherein “circumference” is the length of the border of the selected pore 110. A value of “1” for the circularity represents a perfect circle. The closer the value of circularity approaches zero, the slimmer the shape.

Moreover, in the present embodiment, based on a total amount of 100% of the pores 110, 70% or more of the pores has a diameter s of the pore less than 2.0 μm. In another embodiment, based on a total amount of 100% of the pores 110, 50% or more of the pores has a diameter s of the pore less than 1.5 μm. In yet another embodiment, based on a total amount of 100% of the pores 110, 20% or more of the pores has a diameter s of the pore less than 1.0 μm. The so-called “diameter of pore” refers to the maximum distance between any two points along the border of the selected pore 110.

Moreover, in the present embodiment, based on a total amount of 100% of the pores 110, 90% or more of the pores has an aspect ratio (1/w1) less than 2.5. In another embodiment, based on a total amount of 100% of the pores 110, 80% or more of the pores has an aspect ratio (1/w1) less than 2.0. In yet another embodiment, based on a total amount of 100% of the pores 110, 60% or more of the pores has an aspect ratio (1/w1) less than 1.5. The so-called “aspect ratio” refers to the aspect ratio of fitted ellipse of the pores 110, i.e., the value of (long axis±short axis).

Referring further to FIG. 1A, the pore density of the pores 110 of the present embodiment is between about 6.5×10⁶ ea/cm² and 6.5 ×10⁷ ea/cm². The so-called “pore density” refers to the value of dividing the count of the selected pore 110 by image area.

Moreover, referring to FIG. 1B, the ratio of a depth d and a width w2 of the pores 110 of the present embodiment, i.e., the ratio of depth to diameter (d/w2), is between, for instance, 0.1 and 1.5, which can be obtained from direct observation of the SEM image. The so-called “ratio of depth to diameter” refers to the value of (depth±pore opening diameter) of the selected pore 110.

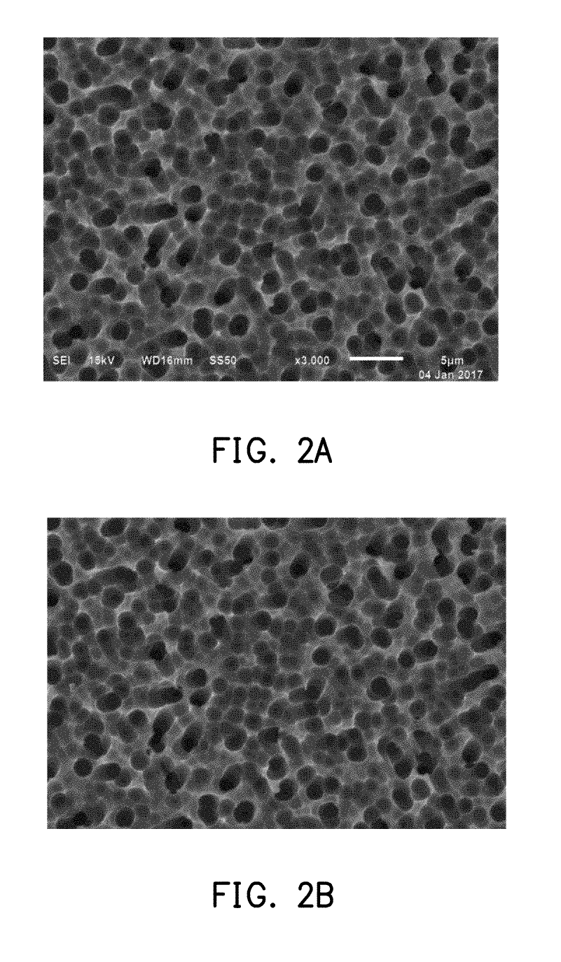

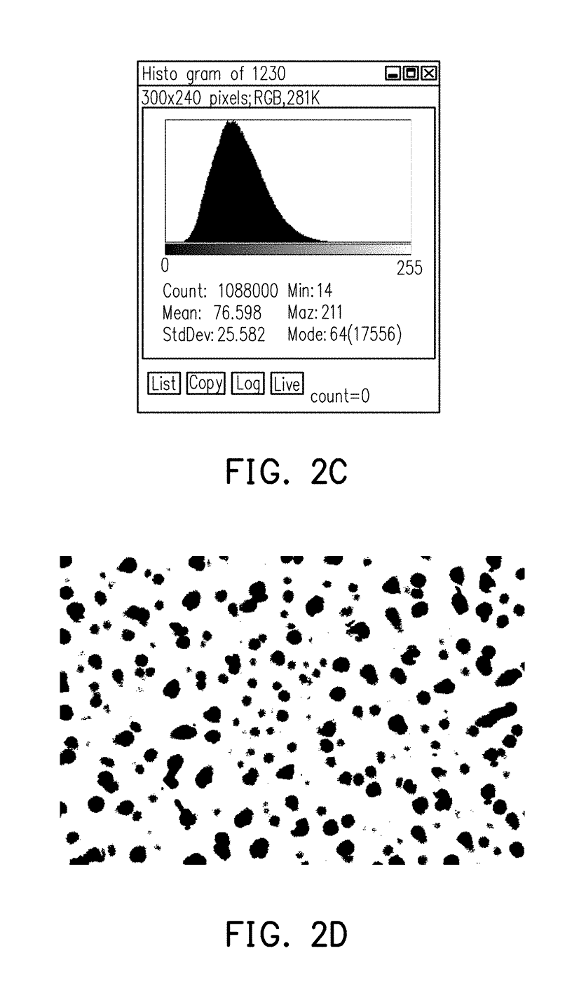

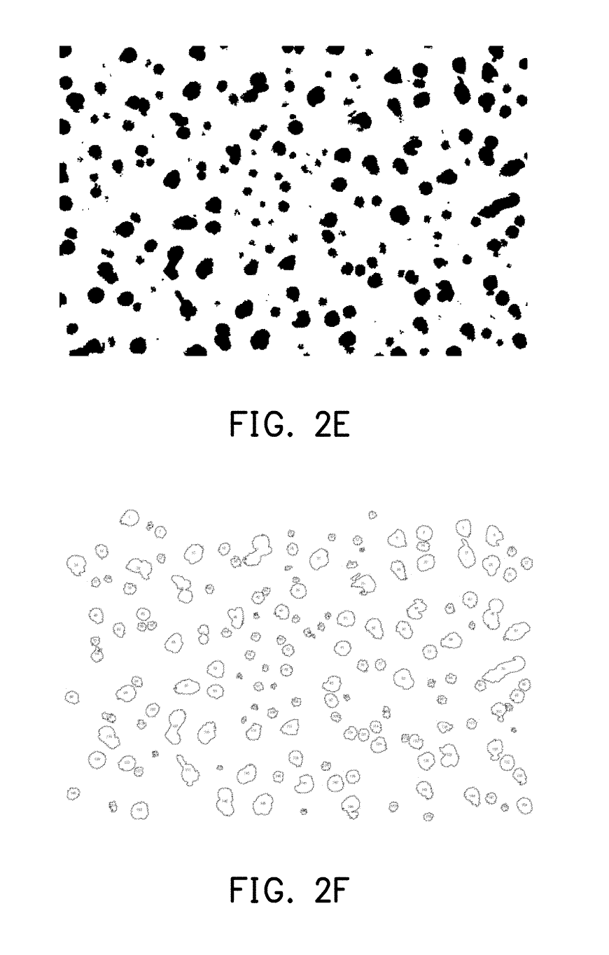

In the present embodiment, the morphology of the pores 110 (such as circularity, diameter of pore, aspect ratio, and pore density) can be obtained from the analysis of the ImageJ software, and the operation of the ImageJ software is as shown in FIG. 2A to FIG. 2F.

First, referring to FIG. 2A, an original image is obtained by fixing an SEM magnification at 3000×, wherein a size of the original image opened by the ImageJ is 1280×960 pxl. Next, the image size is reduced from 1280×960 pxl to 1280×850 pxl to obtain FIG. 2B.

The original grayscale distribution of the original image is analyzed, and the original grayscale distribution is corrected to a distribution of 0 to 255 for obtaining the grayscale calibration curve of FIG. 2C. The new grayscale=(original grayscale-Min)× [255/(Max-Min)], wherein Max refers to a maximum value of the original grayscale, and Min refers to a minimum value of the original grayscale.

Next, the image grayscale threshold is set and selected pore locations are defined to obtain FIG. 2D. The grayscale threshold=0 to 50.

Next, the black and white boundaries are adjusted via a preset function to remove the black spots for obtaining FIG. 2E.

Lastly, incomplete pores at the image edge are removed, and the lower limit of pore size is defined (the size is limited to be from 0.1 μm² to μ, and therefore the lower limit is 0.1 μm²) to obtain FIG. 2F. The morphology of the pores 110 can be obtained via operation according to the pore edge of FIG. 2F.

The preparation of the solar cell wafer of the invention can be performed via the following exemplified steps, but the invention is not limited thereto.

In an embodiment, the preparation of the solar cell wafer can include first soaking a silicon wafer in a salt aqueous solution mixed with a high-reduction potential metal so that the dissolved metal ions can be attached to the silicon wafer surface. The metal ion is, for instance, Au⁺, Ag⁺, Pt²⁺, Pd²⁺, Cu²⁺, etc., wherein Ag⁺ and Cu²⁺ are preferred. Silicon in the region to which the metal ion is attached is oxidized, and silicon oxide is foinied below the metal ion as a result. Next, the silicon wafer taken from the salt aqueous solution is immersed in the next solution that can dissociate fluorine ions, wherein the fluorine ions are reacted with silicon oxide on the silicon wafer surface to dissolve the oxide, and a fine uneven surface is formed as a result. The solution that can dissociate fluorine ions is, for instance, HF, NH₄HF₂, NH₄F, etc., wherein HF is preferred. Next, the silicon wafer is added into an acid to perform etching such that the original uneven surface of the silicon wafer is even more uneven to form significant pores and to dissolve surface metal ions at the same time. The acid is, for instance, HF/HNO₃/CH₃COOH, HF/HNO₃/H₂O, HF/HCl/H₂O, HF/HNO₃/H₂SO₄/H₂O, HF/HNO₃/H₂SO₄/CH₃COOH, etc., wherein HF/HNO₃/CH₃COOH and HF/HNO₃/H₂O are preferred. The etching method can be full basket immersion or passing the wafer through the acid on a track.

In another embodiment, the preparation of the solar cell wafer can include adding an oxidant in the aqueous solution containing fluorine ions to accelerate the oxidation rate of silicon, and the oxidant is, for instance, H₂O₂, HNO₃, HClO₄, O₃, etc., wherein H₂O₂ or HNO₃ is preferred. Next, after silicon oxide is formed below the metal ions, via the method of the previous embodiment, the silicon wafer is first removed and immersed in the next solution that can dissociate fluorine ions, and after a fine uneven surface is formed, the silicon wafer is placed in the acid for etching to form significant pores and to dissolve surface metal ions at the same time.

In yet another embodiment, in the preparation of the solar cell wafer, the oxidant and the solution that can dissociate fluorine ions can be mixed with the salt aqueous solution, and therefore silicon oxidation can be directly promoted and silicon oxide can be dissolved at the same time to form a fine uneven surface.

After the various preparation methods above, a lye can be optionally added to clean acid filth on the silicon wafer surface, wherein the lye is, for instance, KOH, NaOH, etc.

After the various preparation methods above, an acid cleaning can be optionally performed to remove surface residual metal, wherein the acid is, for instance, HF/HCl, HNO₃/H₂O, H₂SO₄/H₂O, etc. Moreover, the acid cleaning can be directly performed without the lye.

Moreover, a washing process with water can be performed between each process above.

Several experimental examples are described below to verify the performance of the invention. However, the invention is not limited hereto.

### EXPERIMENTAL EXAMPLE 1

A silicon wafer for which the surface was cut via a diamond wire (DW) was soaked in a AgNO₃ aqueous solution mixed with a high-reduction potential metal, wherein the content of Ag⁺ ions in the solution was 1 ppb to 10%, the soaking time was 5 seconds to 60 minutes, and the dissolved metal ion Ag⁺ was attached to the silicon wafer surface. Silicon in the region to which the Ag⁺ ion was attached was oxidized, and silicon oxide was formed below the Ag⁺ ion as a result. Next, the silicon wafer removed from the AgNO₃ aqueous solution was immersed in the next solution containing H₂O₂ and HF, wherein HF accounted for 5% to 50% of the total solution volume, H₂O₂ accounted for 1% to 35% of the total solution volume, and the immersion time was 30 seconds to 60 minutes. The dissociated fluorine ions reacted with silicon oxide on the silicon wafer surface to dissolve the oxide, and a fine uneven surface was formed as a result. Next, a third acid mixture containing HF/HNO₃/H₂O was added to etch the wafer by passing the wafer on a track, wherein the mixing ratio of the various acid liquids was 1:1.70-1.80:1.6-1.65, the etching temperature was 3° C. to 12° C., and the etching time was 0.5 minutes to 3 minutes, such that the original uneven surface of the silicon wafer is even more uneven to form significant pores, and surface metal ions are dissolved at the same time. Next, acid filth on the silicon wafer surface was cleaned via a KOH lye having a concentration of 1% to 5%, and then cleaning was performed via an acid mixture of HF/HCl/H₂O, wherein the mixing ratio of the various acid liquids was 1:2.5-2.7:14-15 to remove surface residual metal.

### EXPERIMENTAL EXAMPLE 2

A silicon wafer for which the surface was cut via a diamond wire (DW) was processed using the method of experimental example 1, but the etching temperature was changed to 6° C. to 8° C., and the etching time was 1 minute to 2 minutes.

### COMPARATIVE EXAMPLE 1

A silicon wafer for which the surface was cut via a traditional slurry wire (SW) was placed in the same third acid mixture as experimental example 2 to perform the same etching, and lastly the silicon wafer was immersed in KOH and cleaned via a HF/HCl/H₂O acid mixture as experimental example 1.

### COMPARATIVE EXAMPLE 2

A silicon wafer cut by a diamond wire (DW) was processed in the same manner as comparative example 1.

<Analysis>

(1) Sampling method: each silicon wafer after surface treatment was divided into 9 equal squares, and samples were taken from any two cracks or cuts.

(2) Equipment: SEM.

(3) Magnification: 3000× to 5000×.

(4) Image capture: Top view of silicon wafer sample (mainly captured with 3000×), cross section of silicon wafer sample (mainly captured with 5000×).

(5) Pore morphology analysis: An image of the silicon wafer looking down was captured, and the following items were analyzed with open ImageJ software.

a. Diameter of pore;

b. Pore density;

c. Circularity;

d. Aspect ratio;

e. Pore area ratio.

(6) The ratio of depth to diameter of the pores in the image were directly observed according to the cross section of the silicon wafer sample without software analysis.

(7) Measurement method of reflectance: the reflectance of the silicon wafer sample was measured at a wavelength of 650 nm using a D8 integral reflectometer. Measurement was performed for each sheet at 9-point locations of the nine divided squares.

(8) Measurement method of conversion efficiency: the silicon wafer samples were applied in solar cell production, and then the photoelectric conversion efficiency thereof was measured at an illumination power of 1000 mW/cm².

<Results>

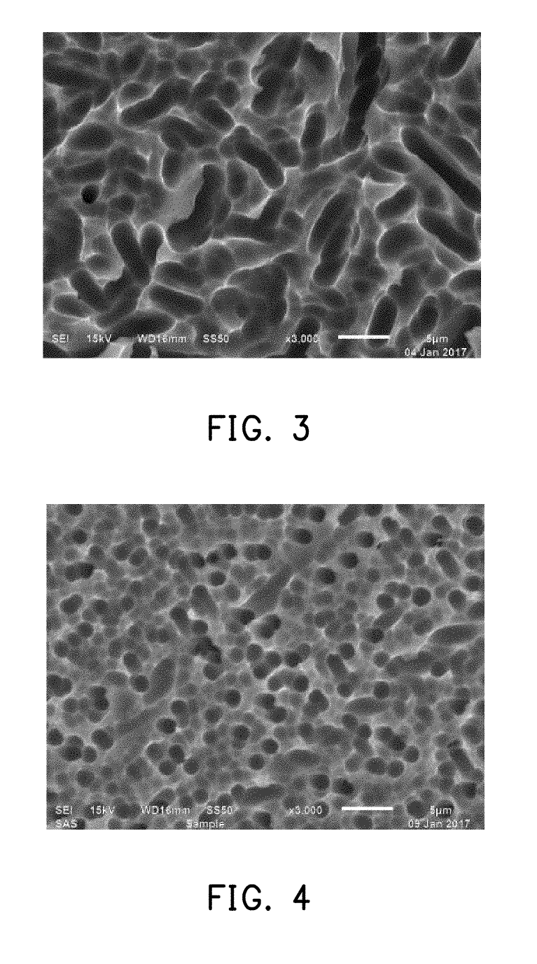

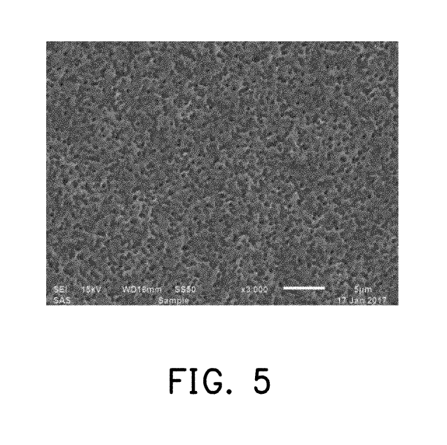

FIGS. 3 to 5 are respectively images of comparative example 1 and experimental examples 1-2 obtained by the ImageJ software. It can be known from FIGS. 3 to 5 that, the pore image of comparative example 1 is significantly different from the images obtained in experimental examples 1-2.

Next, the morphologies of the pores in comparative example 1 and experimental examples 1-2 were obtained according to the operating settings of the ImageJ software, and the results are shown in Table 1 below.

TABLE 1

| | Comparative | Experimental | Experimental |
|---|---|---|---|
| | example 1 | example 1 | example 2 |
| Diameter of pore (μm) | 2.568 | 1.542 | 0.6267 |
| Pore density (ea/μm²) | 0.0631 | 0.1059 | 0.4105 |
| Pore area ratio (%) | 17.29 | 16.29 | 7.278 |
| Aspect ratio | 2.083 | 1.337 | 1.574 |
| Circularity | 0.39 | 0.56 | 0.74 |

It is obvious from Table 1 that, the pore density has a scale of millions per cm² in comparative example 1; and experimental examples 1 to 2 can reach a scale of tens of millions per cm². Moreover, the circularity of comparative example 1 is smallest, and the circularity of experimental examples 1 to 2 is largest, wherein the circularity is defined as “4π×pore area/pore circumference”, and therefore the closer the pores are to a circle, the closer the circularity thereof is to 1. Moreover, the pore area ratio of Table 1 is defined as all of the pore areas on the wafer calculated with the ImageJ software divided by the wafer area. In comparative example 1, since the diameter of pore is greater, the pore area ratio is higher, and in experimental examples 1 to 2, the diameter of pore is smaller, and therefore the pore area ratio is less than that of the comparative example.

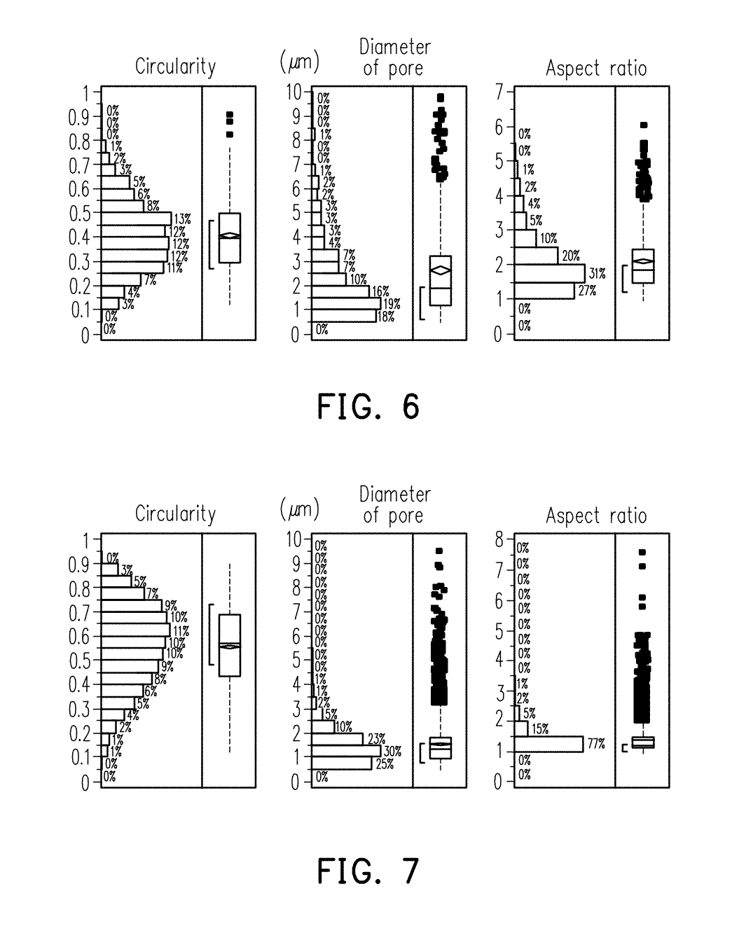

FIGS. 6 to 8 are respectively bar diagrams of the pore morphology of comparative example 1 and experimental examples 1 to 2 obtained by the ImageJ software.

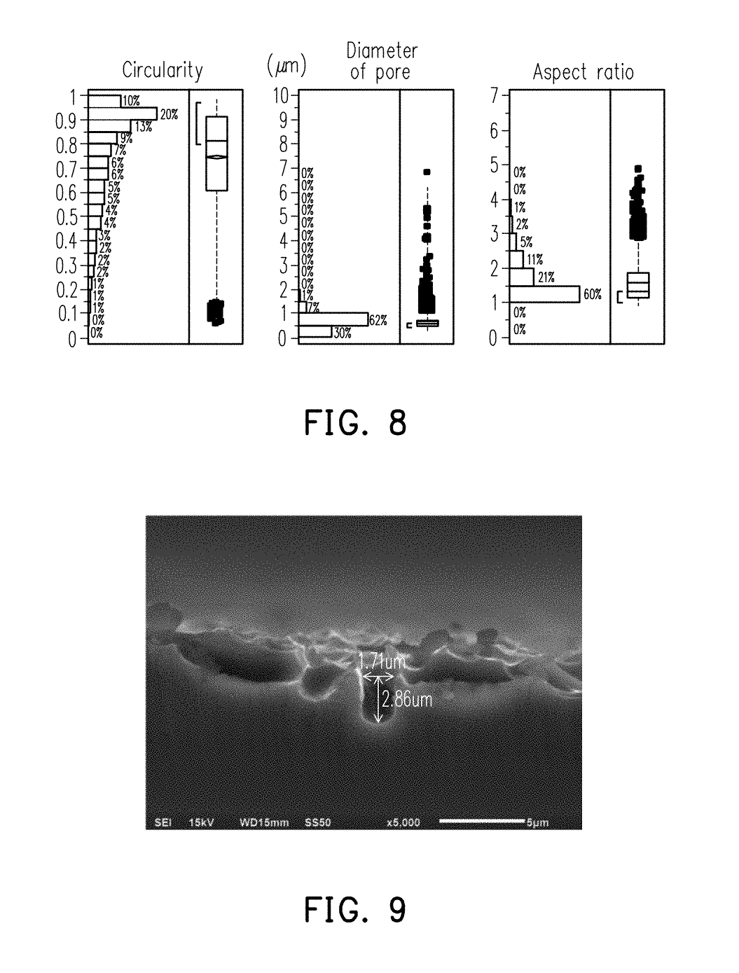

It is clear from FIGS. 6 to 8 that, 65% of the pores of experimental example 1 has a circularity greater than 0.5, and 85% of the pores of experimental example 2 has a circularity greater than 0.5, but only 25% of the pores of comparative example 1 has a circularity greater than 0.5. The results of Table 2 can be obtained by counting based on FIGS. 7 to 8.

TABLE 2

| Pore | Experimental | Experimental | Comparative |
|---|---|---|---|
| morphology | example 1 | example 2 | example 1 |
| Diameter of | 78% of | 100% of | 53% of |
| pore (μm) | pores <2.0 μm | pores <2.0 μm | pores <2.0 μm |
| | 55% of | 99% of | 37% of |
| | pores <1.5 μm | pores <1.5 μm | pores <1.5 μm |
| | 25% of | 92% of | 18% of |
| | pores <1.0 μm | pores <1.0 μm | pores <1.0 μm |
| Aspect ratio | 97% of | 92% of | 78% of |
| | pores <2.5 | pores <2.5 | pores <2.5 |
| | 92% of | 81% of | 58% of |
| | pores <2.0 | pores <2.0 | pores <2.0 |
| | 77% of | 60% of | 27% of |
| | pores <1.5 | pores <1.5 | pores <1.5 |
| Circularity | 65% of | 85% of | 25% of |
| | pores >0.5 | pores >0.5 | pores >0.5 |
| | 45% of | 74% of | 11% of |
| | pores >0.6 | pores >0.6 | pores >0.6 |
| | 24% of | 65% of | 3% of |
| | pores >0.7 | pores >0.7 | pores >0.7 |

It is clear from Table 2 that, the pore morphology of comparative example 1 and the pore morphology of experimental examples 1 to 2 are significantly different.

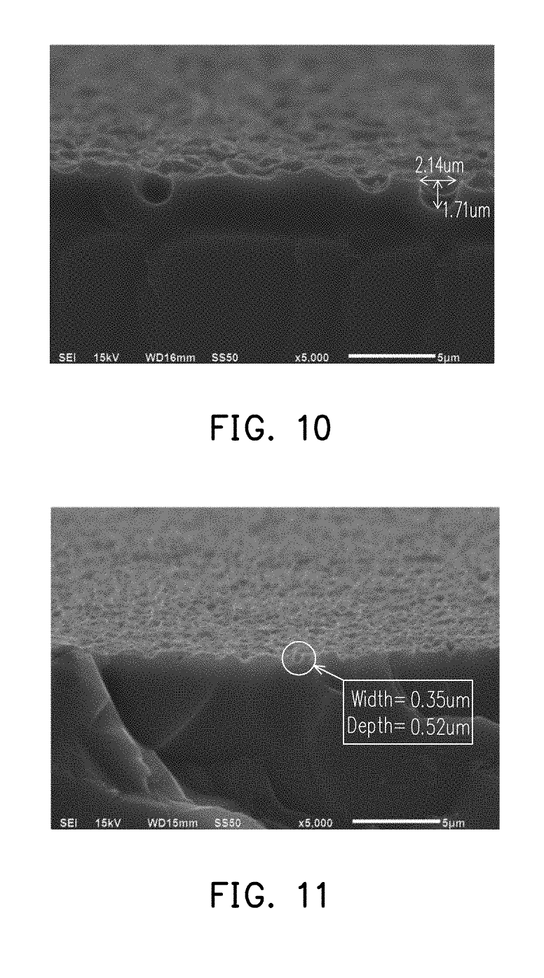

FIGS. 9 to 11 are respectively 10,000× SEM images of the solar cell wafer cross sections of comparative example 1 and experimental examples 1-2. Table 3 was obtained via manual estimation and counting.

TABLE 3

| | Comparative | Experimental | Experimental |
|---|---|---|---|
| | example 1 | example 1 | example 2 |
| A ratio of depth to | 0.2 to 1.70 | 0.1 to 1.0 | 0.1 to 1.50 |
| diameter of the pore | | | |

(Definition: average ratio of depth to diameter of any 2 points or more (including 2 points) of each sheet)

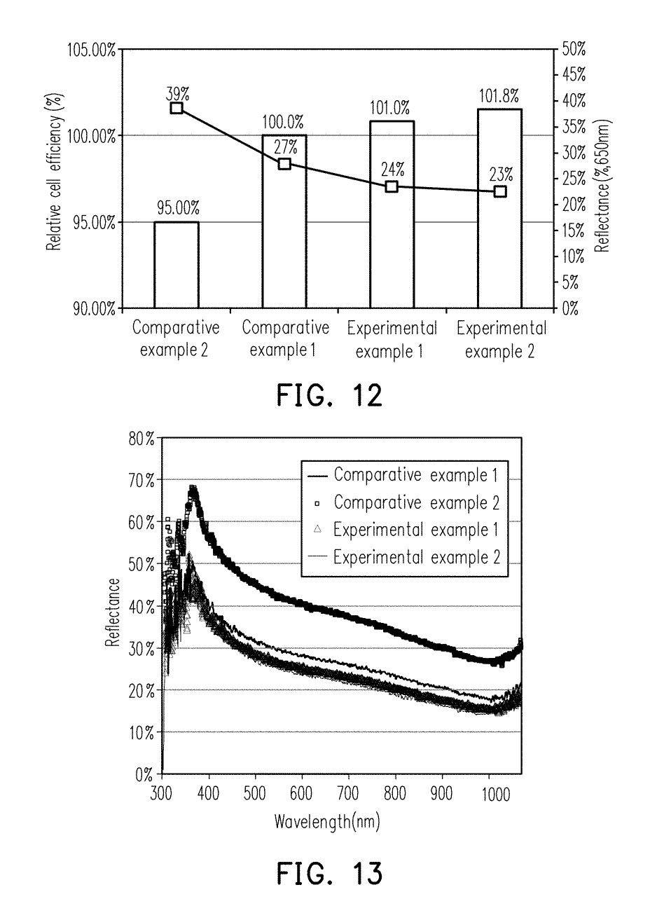

FIG. 12 is a comparison diagram of reflectance and efficiency of experimental examples 1-2 and comparative examples 1-2. It can be known from FIG. 12 that, in comparison to comparative examples 1-2, the conversion efficiency and reflectance of experimental examples 1-2 are significantly improved. Overall, the reflectance measured at 650 nm can be improved to 4%.

FIG. 13 is a curve diagram of reflectance of experimental examples 1-2 and comparative examples 1-2. It is more obvious from the reflectance curve of FIG. 13 that, the reflectance of experimental examples 1-2 of the invention is lower than the reflectance of comparative examples 1-2 within the wavelength range of 300 nm and 1100 nm.

Based on the above, the silicon wafer surface of the invention has a specific morphology, and therefore the reflectance thereof can be effectively reduced, such that the photoelectric conversion efficiency of the solar cell is increased. Moreover, the silicon wafer surface is analyzed with an image analysis software (ImageJ software) with a specific operating setting, and therefore a specific morphology that can achieve the effects above can be accurately obtained.

Although the invention has been described with reference to the above embodiments, it will be apparent to one of ordinary skill in the art that modifications to the described embodiments may be made without departing from the spirit of the invention. Accordingly, the scope of the invention is defined by the attached claims not by the above detailed descriptions.

What is claimed is:

1. A solar cell wafer made of silicon, wherein:
a surface of the silicon wafer has a plurality of pores, wherein
based on a total amount of 100% of the pores, 60% or more of the pores has a circularity greater than 0.5.

2. The solar cell wafer of claim 1, wherein based on a total amount of 100% of the plurality of pores, 40% or more of the pores has a circularity greater than 0.6.

3. The solar cell wafer of claim 1, wherein based on a total amount of 100% of the plurality of pores, 20% or more of the pores has a circularity greater than 0.7.

4. The solar cell wafer of claim 1, wherein based on a total amount of 100% of the plurality of pores, 70% or more of the pores has a diameter of pore less than 2.0 μm.

5. The solar cell wafer of claim 1, wherein based on a total amount of 100% of the plurality of pores, 50% or more of the pores has a diameter of pore less than 1.5 μm.

6. The solar cell wafer of claim 1, wherein based on a total amount of 100% of the plurality of pores, 25% or more of the pores has a diameter of pore less than 1.0 μm.

7. The solar cell wafer of claim 1, wherein based on a total amount of 100% of the plurality of pores, 90% or more of the pores has an aspect ratio less than 2.5 μm.

8. The solar cell wafer of claim 1, wherein based on a total amount of 100% of the plurality of pores, 80% or more of the pores has an aspect ratio less than 2.0 μm.

9. The solar cell wafer of claim 1, wherein based on a total amount of 100% of the plurality of pores, 60% or more of the pores has an aspect ratio less than 1.5 μm.

10. The solar cell wafer of claim 1, wherein a pore density of the plurality of pores is between 6.5 ×10⁶ ea/cm² and 6.5 ×10⁷ ea/cm².

11. The solar cell wafer of claim 1, wherein a morphology of the plurality of pores is obtained by an analysis of an ImageJ software, and an operation of the ImageJ software has the following settings:
obtaining an original image by fixing an SEM magnification at 3000×wherein a size of the original image opened by the ImageJ is 1280×960 pxl;
changing the size from 1280×960 pxl to 1280×850 pxl;
analyzing a grayscale distribution of the original image and correcting the grayscale distribution to a 0 to 255 distribution, wherein new grayscale=(original grayscale-Min)×[255/(Max-Min)], Max refers to a maximum value of the original grayscale, and Min refers to a minimum value of the original grayscale;
setting an image grayscale threshold and defining selected pore locations, wherein the grayscale threshold=0 to 50;
adjusting black and white boundaries via a preset function and removing a plurality of black spots; and
removing an incomplete pore at an image edge and defining a lower limit of a pore size, wherein the lower limit is 0.1 μm².

12. The solar cell wafer of claim 1, wherein a ratio of depth to diameter of the pore is between 0.1 and 1.5.

13. The solar cell wafer of claim 1, wherein the surface of the silicon wafer is a light-receiving surface.

14. The solar cell wafer of claim 1, wherein a reflectance of the surface of the silicon wafer is 25% or less.
